(19) United States
(12) Patent Application Publication
(10) Pub. No.: US 2026/0313246 A1
(43) Pub. Date: Oct. 8, 2026

(54) INTEGRATION OF A DEVICE ON A READ-OUT MATRIX

(71) Applicants: COMMISSARIAT À L'ENERGIE ATOMIQUE ET AUX ENERGIES ALTERNATIVES, PARIS (FR); TRIXELL, MOIRANS (FR)

(72) Inventors: Jean-Marie VERILHAC, GRENOBLE (FR); Mohammed BENWADIH, GRENOBLE (FR); Stéphanie LOMBARD, GRENOBLE (FR)

(21) Appl. No.: 19/478,796

(22) PCT Filed: Apr. 24, 2024
(86) PCT No.: PCT/EP2024/061206

§ 371 Date: Oct. 24, 2025

(30) Foreign Application Priority Data
Apr. 27, 2023 (FR) FR2304290

(51) Int. Cl. H04N 25/10; H04N 25/78

(52) U.S. Cl. CPC H04N 25/10; H04N 25/78

(57) ABSTRACT

An optoelectronic device includes at least one pixel including an absorption layer made of a first material and arranged on a first face of a first substrate, the absorption layer being intended to convert incident radiation into electrical charges; a lower electrode for collecting the electrical charges; and an upper electrode arranged on the absorption layer; a readout circuit arranged on a second substrate and having at least one readout electrode dedicated to the pixel; the first substrate includes at least one via starting from a second face of the first substrate opposite the first face; the via being electrically connected on the one hand to the lower electrode and on the other hand to at least one hybridization connector for electrically and mechanically coupling the pixel to the readout electrode dedicated to the pixel.

### CROSS-REFERENCE TO RELATED APPLICATIONS

This application is a National Stage of International patent application PCT/EP 2024/061206, filed on Apr. 24, 2024, which claims priority to foreign French patent application No. FR 2304290, filed on Apr. 27, 2023, the disclosures of which are incorporated by reference in their entireties.

### FIELD OF THE INVENTION

The invention relates to hybrid systems, i.e. systems consisting of two separate parts assembled by an assembly layer, each part being made of a different material. These systems may be optical, electronic or optoelectronic, depending on the features of the assembled parts. The invention particularly relates to the integration of at least one photodetector structure based on a photoconductive material into a pixel matrix so as to form an imaging device.

### BACKGROUND

Hybrid systems allow the combination of two functionalities made of different materials. Examples include:
a detector, in which the sensitive part is combined with a readout circuit to allow collection and processing of the signal to be detected,
a display, for example of the electroluminescent type, in which the emitting part is combined with a circuit for generating electrical signals suitable for emission.

In particular, the technical field relates to the production of optoelectronic hybrid systems, comprising: a photo-conversion part based on at least one photosensitive element for generating electrical charge carriers from incident photons; and an electronic part consisting of a readout circuit totally or partly mounted on a substrate and enabling the signal from each pixel of the photo-conversion part to be read individually. In general, the photo-conversion part comprises an absorption layer confined between two electrodes. The absorption layer converts the stream of incident photons with a wavelength A into negative charge carriers (“electrons”) in the conduction band and positive charges (“holes”) in the valence band. The materials used to make the absorption layer and the thickness of the absorption layer determine the frequency and amount of radiation absorbed.

Optoelectronic devices intended for the direct detection of ionizing radiation (X-rays) require absorption layers with larger lateral dimensions (width, length) relative to other optical detection devices. Conventional materials used to make absorption layers in this range are either incompatible with these large dimensions and reasonable manufacturing costs (single-crystal CdTe or Zn-doped single-crystal CdTe, for example), or limited in absorption for the high energies required for radiography (amorphous selenium, for example).

In the present context, semiconductor materials with a perovskite-type crystal structure have emerging solutions for the creation of absorption and photo-conversion structures in optoelectronic devices. This type of material makes it possible to produce absorption layers with lateral dimensions greater than 10 cm while at the same time maintaining photo-conversion performance comparable to that of conventional materials. However, coupling a photo-conversion part based on an absorption layer with a perovskite-type crystal structure to the electronic part presents several technical problems arising from the mechanical, chemical and thermal characteristics of perovskites. In the context of the description of the invention, the term “coupling” means the set of specific operations and techniques for combining two parts having different functions (for example the readout circuit and the photodetector array). In the context of the description of the invention, the term “perovskite layer” means a layer made of a material of perovskite-type crystal structure or a structure similar to perovskites. In the context of the invention, the perovskites used may be OD perovskites, 1D perovskites, 2D perovskites, 3D perovskites, or a mixture of these different perovskites.

A 0D perovskite is a perovskite-based crystalline material with a zero-dimensional nanometric structure. This means that the atoms in the crystal structure are arranged uniformly in a nanometric configuration. 0D perovskites are often considered as nanoparticles, nanocrystals or nanocomposites.

A 1D perovskite is a crystalline perovskite-based material with a linear one-dimensional structure. This means that the atoms in the crystal structure are arranged uniformly along a single direction. 1D perovskites may take the form of nanowires, nanotubes or nanofibers.

A 2D perovskite is a crystalline perovskite-based material with a two-dimensional planar structure. This means that the atoms in the crystal structure are arranged in a uniform manner on a flat surface. 2D perovskites may take the form of ultra-thin sheets or membranes.

A 3D perovskite is a crystalline perovskite-based material with a three-dimensional structure. This means that the atoms in the crystal structure are arranged in a uniform manner in three-dimensional space. 3D perovskites may take the form of bulk crystals or crystalline powders.

The integration of a thick layer having a perovskite-type crystal structure onto a substrate, notably the electronic part of a hybrid system, presents several technical constraints. Specifically, there is no industrializable large-scale, cost-competitive coupling technology that allows this type of material to be integrated into a hybrid system without degrading the mechanical, optical and/or electronic features of the hybrid system.

In general, two types of conventional integration techniques are used to assemble a photoconductive layer on a readout matrix: “direct” integration and “indirect” integration (or hybridization).

Direct integration consists in depositing an absorption layer directly onto the readout circuit. Direct integration in this case raises several technological issues. For example, the high thermal budget required for depositing a perovskite absorption layer by vacuum deposition or melting reduces the robustness of the electronic components of the readout circuit (transistors, metal tracks, etc.). Furthermore, the temperatures applied during deposition cause differential thermal expansion between the absorption layer and the substrate of the electronic part of the optoelectronic device. This embrittles the mechanical structure of the absorption layer and causes adhesion problems at the interfaces of said layer. Furthermore, direct deposition may cause chemical reactivity problems between the metal tracks of the readout circuit and the deposited perovskite absorption layer. Thus, direct integration is not the preferred solution for integrating a perovskite-based photodetector structure onto a readout circuit.

Indirect integration (or hybridization) consists in producing the electronic part and the photo-conversion part separately and then assembling them using hybridization methods (also known as coupling techniques). The hybridization of an optoelectronic system raises the following interdependent technological issues:
the assembly of the photo-conversion part and the electronic part mechanically without affecting the optoelectronic and/or electrical performance of the hybrid device;
interconnection, consisting in creating an electrical interconnection architecture between each of the pixels in the readout matrix and the corresponding detector device.

### SUMMARY OF THE INVENTION

Thus, the present invention proposes an indirect integration technique for solving the problems associated with coupling a thick perovskite layer to a readout circuit. The description of the invention, detailed hereinbelow, based on a perovskite layer, is given for nonlimiting illustrative purposes. The invention extends to materials other than perovskites, such as cadmium telluride (CdTe), zinc-doped cadmium telluride (CZT), amorphous selenium (Se), lead oxide (PbO), mercury iodide (HgI2), and lead iodide (PbI₂). These materials may possibly be in single-crystal and/or polycrystalline form.

To better understand the problem addressed by the invention, to begin with a description will be given of the structure of a radiation detection device manufactured by hybridization according to the prior art. To do this, the case of a perovskite hybridized on a pixel matrix manufactured on a CMOS circuit will be considered.

FIG. 1 illustrates a partial cross section of a prior art optoelectronic hybrid system having an optoelectronic part comprising a perovskite absorption layer.

The optoelectronic device D0 illustrated in FIG. 1 is an ionizing radiation detector. It is made up of a photo-conversion part D0_opt comprising at least one pixel Pxl₀ and an electronic part D0_elec comprising a readout circuit ROIC and a plurality of readout electrodes EL_read connected to a readout circuit ROIC.

The readout integrated circuit ROIC is produced using at least one transistor and thin layers of conductive, semiconductor or dielectric materials according to CMOS (Complementary Metal-Oxide-Semiconductor) technology on a substrate sub2. For each pixel Pxl₀, a readout electrode EL_read is associated to read the signals generated by the photo charge carriers generated by the photodetector structure of a pixel Pxl₀.

As regards the photo-conversion part of the device, it comprises, for each pixel, an absorption and photo-conversion layer AL common to all pixels, an upper electrode EL2 common to all pixels, and a lower electrode EL1 for collecting the generated charges. In the case of the architecture described in FIG. 1, hybridization is performed for each pixel by means of a metal bead CEM that electrically connects the readout electrode EL_read to the lower electrode EL1 associated exclusively with the same pixel. The bead CEM can, for example, be made of indium beads or copper micro-pillars, allowing each pixel to have individualized contact with the readout circuit ROIC.

In the case of a perovskite absorption layer deposited over a large area, the perovskite surface on which the lower electrodes EL1 are deposited is rough. Furthermore, this surface is not perfectly flat because the surface state of thick perovskite layers is difficult to control during manufacture. Furthermore, the manufacture of conductive lower electrodes EL1, with a small matrix pitch (~50-200 um), over large areas and on perovskite materials that are chemically sensitive to the resins, solvents, and etching agents used in photolithography, is very difficult. For these reasons, it is difficult to envisage depositing the lower electrodes EL1 on the perovskite surface and to perform the hybridization step as described previously on the perovskite surface due to chemical, topological, thermal and mechanical constraints. These problems related to the state of the surface onto which the lower electrodes EL1 are deposited (roughness, uneven flatness) limit the spatial resolution of the detector because the spacing between the lower electrodes EL1 is no longer controlled.

Thus, it has been demonstrated that prior art technical solutions of methods for pixellation, assembly and interconnection on readout circuits are not optimal for an optoelectronic system based on a perovskite absorption layer. The same problems relating to chemical, thermal and mechanical incompatibility are also present in the following photodetection materials: cadmium telluride (CdTe), zinc-doped cadmium telluride (CZT), amorphous selenium (Se), lead oxide (PbO), mercury iodide (HgI₂), and lead iodide (PbI₂). These materials may be in single-crystal and/or polycrystalline form.

The scientific publication “High-sensitivity high-resolution X-ray imaging with soft-sintered metal halide perovskites” by Deumel et al. describes a process for manufacturing perovskite pellets by low-temperature powder compaction. The process described includes an assembly layer made by liquefying MAPbI3 powder.

The drawback of the solution described is that the composition of the assembly layer used has an impact on the optoelectronic performance of the absorption layer. The nature, morphology and contact surface with the substrate of the assembly layer modify the optoelectronic feature of the detector as a whole. Furthermore, the MAPbI3 liquefaction operation is not well controlled, making this process incompatible with industrial-scale production and on the large surface areas targeted for detectors. Several problems arise relating to the liquefied layer drying too quickly and the loss of material due to the removal of the solvent during the drying step.

To overcome the limitations of existing solutions with regard to the hybridization of an optoelectronic device comprising at least one photodetector structure connected to a single readout electrode of a readout circuit, the invention proposes several embodiments of an assembled hybrid system architecture. More particularly, the invention proposes a mode of integration by indirect coupling suitable for the constraints of integrating thick layers of absorption photodetectors used for direct detectors for ionizing radiation.

The device according to the invention is based on the manufacture of a thick absorption photodetector layer on a first substrate that is compatible with the manufacturing conditions of said layer. The photodetector layer is made of perovskite or cadmium telluride (CdTe) or cadmium telluride doped with zinc (CZT), or amorphous selenium (Se), or lead oxide (PbO), or mercury iodide (HgI₂) or lead iodide (PbI₂). The first substrate according to the invention assures mechanical assembly and electrical continuity between the electronic part and the photo-conversion part.

The invention makes it possible to disocciate the manufacturing constraints of the absorption layer from the mechanical, thermal, chemical and electrical constraints associated with the materials and hybridization processes on the readout circuit and its substrate.

Furthermore, the invention allows a substrate to be used for the growth (or deposition) of the thick absorption layer with suitable properties (mechanical, thermal, chemical, electrical) to facilitate the direct deposition of said layer.

The invention also aids in overcoming the problems of chemical compatibility, surface state, flatness, and roughness of thick absorption layers encountered in prior art hybridization solutions. It also offers the possibility of reducing the lateral distance between the lower electrodes and thus reducing the pixellization pitch so as to increase the resolution of the detector.

More generally, the use of indirect integration according to the invention is considered advantageous from an industrial point of view because it allows certain critical steps related to the manufacturing technology of the readout circuit to be separated from the steps for manufacturing the photodetector structure (EL1, AL, EL2). Each of these two technological components can be manufactured, characterized and tested separately before assembly.

One subject of the invention is an optoelectronic device comprising:
at least one pixel comprising:
an absorption layer made of a first material and arranged on a first face of a first substrate, the absorption layer being intended for converting incident radiation into electrical charges;
a lower electrode for collecting electrical charges;
and an upper electrode arranged on the absorption layer;
a readout circuit arranged on a second substrate and comprising at least one readout electrode dedicated to the pixel;
the first substrate comprising at least one via starting from a second face of the first substrate opposite said first face; said via being electrically connected on the one hand to the lower electrode and on the other hand to at least one hybridization connector for electrically and mechanically coupling the pixel to the readout electrode dedicated to said pixel.

According to a particular aspect of the invention, the first material is a perovskite or cadmium telluride or cadmium telluride doped with zinc or amorphous selenium or lead oxide or mercury iodide or lead iodide.

According to a particular aspect of the invention, the via opens from the second face of the first substrate to the first face of the first substrate.

According to a particular aspect of the invention, the pixel also comprises, for each via, an electrically conductive upper interface layer deposited onto the first face of the first substrate; the upper interface layer being confined between the end of the associated via and a volume of the absorption layer.

According to a particular aspect of the invention, at least the via and/or the upper interface layer constitutes a blocking layer for a predetermined type of charge carrier.

According to a particular aspect of the invention, the pixel also comprises, for each via, an electrically conductive lower interface layer deposited onto the second face of the first substrate; the lower interface layer being in contact with the lower end of the associated via.

According to a particular aspect of the invention, the width of the lower interface layer is less than the separation distance between two adjacent readout electrodes.

According to a particular aspect of the invention, the via is filled with a second electrically conductive material.

According to a particular aspect of the invention, the inner walls of the via are covered with a second electrically conductive material.

According to a particular aspect of the invention, the via is filled with a dielectric material.

According to a particular aspect of the invention, the assembly formed by the upper interface layer, the via, and the lower interface layer forms a capacitive element suitable for storing the electrical charges generated.

According to a particular aspect of the invention, the via is filled with a stack comprising a dielectric material confined between two electrically conductive materials so as to form a capacitive element in the via suitable for storing the electrical charges generated.

According to a particular aspect of the invention, the via does not open onto the first face of the first substrate from the second face of the first substrate. The first substrate is made of a dielectric or semiconductor material; the via is conductive.

According to a particular aspect of the invention, the first substrate has a crystal structure that matches the lattice of the first material.

According to a particular aspect of the invention, the first substrate is opaque to wavelengths in the visible range and/or to X-rays or gamma rays.

According to a particular aspect of the invention, the first material is CsPbBr₃ perovskite.

A subject of the invention is also a matrix image sensor comprising an optoelectronic device according to the invention.

Other features and advantages of the present invention will emerge more clearly on reading the following description in conjunction with the accompanying drawings.

### BRIEF DESCRIPTION OF THE DRAWINGS

FIG. 1 illustrates a cross-sectional view of an example of hybridization of an optoelectronic device according to the prior art. This figure has already been described.

FIG. 2a illustrates a cross-sectional view of an example of hybridization of an optoelectronic device according to a first embodiment of the invention.

FIG. 2b illustrates a cross-sectional view of an example of hybridization of an optoelectronic device according to a second embodiment of the invention.

FIG. 2c illustrates a cross-sectional view of an example of hybridization of an optoelectronic device according to a third embodiment of the invention.

FIG. 2d illustrates a cross-sectional view of an example of hybridization of an optoelectronic device according to a fourth embodiment of the invention.

FIG. 2e illustrates a cross-sectional view of an example of hybridization of an optoelectronic device according to a fifth embodiment of the invention.

FIG. 3 illustrates a cross-sectional view of an example of hybridization of an optoelectronic device according to a sixth embodiment of the invention.

FIG. 4 illustrates a cross-sectional view of an example of hybridization of an optoelectronic device according to a seventh embodiment of the invention.

FIG. 5 illustrates a cross-sectional view of an example of hybridization of an optoelectronic device according to an eighth embodiment of the invention.

FIG. 6 illustrates the steps in a process for manufacturing an optoelectronic device according to the invention.

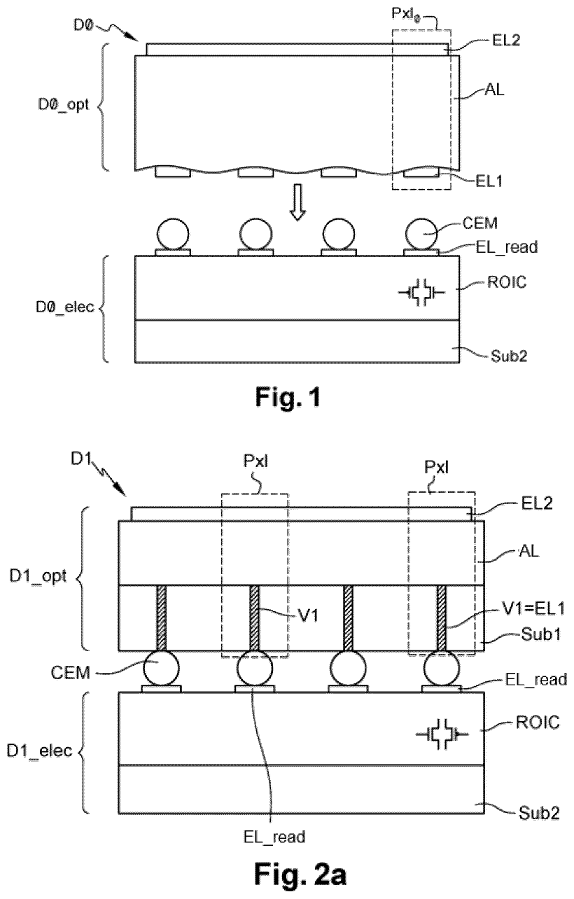

### DETAILED DESCRIPTION

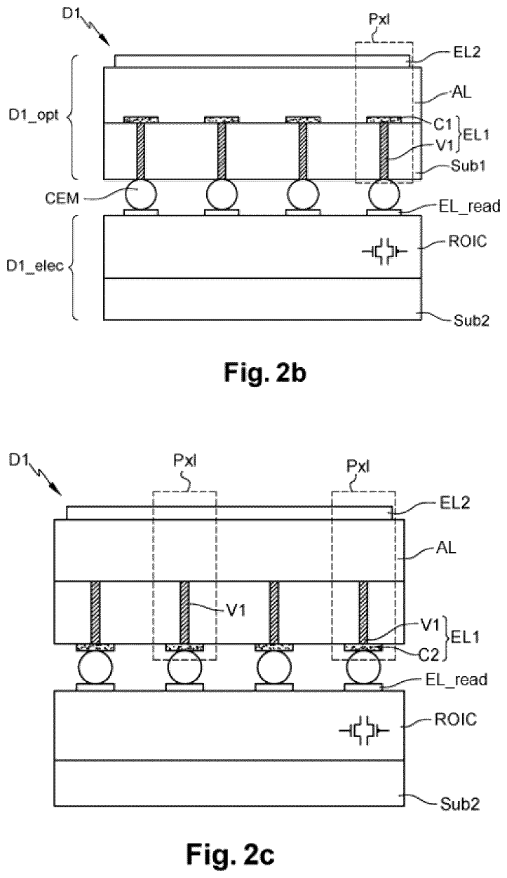

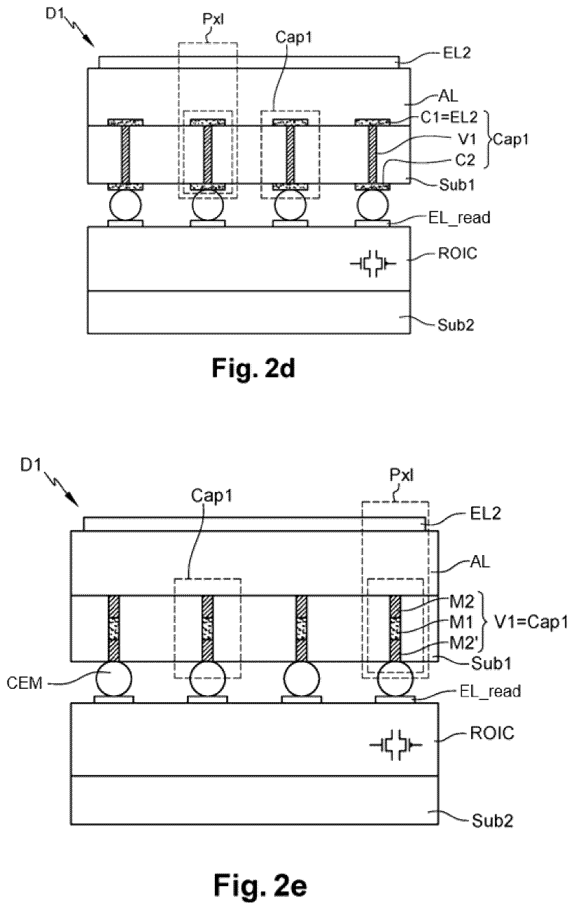

FIG. 2a illustrates a cross-sectional view of an example of hybridization of an optoelectronic device D1 according to a first embodiment of the invention. The optoelectronic device D1 is intended to detect ionizing radiation, by way of example. It is emphasized that the various features of the invention are not limited to the application described and remain compatible with all hybrid devices requiring the assembly of a layer to the electronic part of said hybrid device.

The optoelectronic device D1 comprises any photo-conversion part D1_opt based on at least one pixel Pxl for generating electrical charge carriers from incident photons; and an electronic part D1_elec consisting of a readout circuit ROIC comprising a plurality of readout electrodes EL_read to allow individual reading of the signal from each pixel Pxl of the photo-conversion part.

The readout circuit ROIC consists of a transistor-based processing chain implemented totally on the second substrate sub2. Alternatively, the readout circuit ROIC is partially implemented on the second substrate sub2. By way of example, only the selection transistors associated with each pixel are implemented on the second substrate sub2. The electrical signals generated by photo-conversion are propagated to an external processing chain implemented on another substrate not shown. Alternatively, the second substrate sub2 only supports conductive transmission lines intended to propagate electrical signals generated to an external processing chain implemented on another substrate not shown. The invention is compatible with the three abovementioned readout circuit ROIC implementation configurations.

Each pixel Pxl comprises an absorption layer AL, an upper electrode EL2, and a lower electrode EL1 for collecting the generated charges. The absorption layer AL is made of a first perovskite-type material and is arranged on a first face of a first substrate sub1.

The absorption layer AL is intended for converting incident radiation into electrical charges. In the illustrated case and without loss of generality, the absorption layer is common to all pixels Pxl of the optoelectronic device D1. Alternatively, it is possible to delimit the absorption layer AL for each pixel by introducing dielectric separation structures to delimit each absorption layer AL of a pixel Pxl, or by localizing the layer via lithography techniques, for example. The materials used to make the absorption layer AL and its thickness determine the frequency and amount of radiation absorbed by said absorption layer. When the device D1 is intended for the detection of ionizing radiation (X-rays, gamma rays, ionizing particles, etc.), the first material is, for example, a material from the perovskite family or perovskite derivatives. The first material is a compound material ABX₃ with:
A selected from a first set of elements including:
   inorganic cations such as cesium Cs, rubidium Rb, potassium K, sodium Na or lithium Li;
   organic cations such as MA (methylammonium)=CH₃—NH₃⁺, FA (formamidinium)=CH₅N₂⁺, GA (guanidinium)=CH₆N₃⁺; EA (ethylammonium)=CH₃CH₂NH₃⁺; DMA (dimethylammonium)=C₂H₆NH₂⁺; AC (acetamidinium)=C₂H₃N₂H₄⁺; AZ (azetidinium)=C₃H₆NH₂⁺; TBA (tetrabutylammonium)=C₄H₉NH₃⁺; PYRI (pyridium)=C₅H₅NH⁺; PYRO (pyrrolidium)=C₄H₈NH₂⁺; isoP (iso-propylammonium)=C₃H₇NH₃⁺; PIP (piperidium)=C₅H₁₀NH₂⁺
   or an alloy of said elements from the first set of elements;
B selected from a second group of elements including:
   inorganic cations such as lead Pb, tin Sn, germanium Ge, silicon Si, strontium Sr, barium Ba, europium Eu, thulium Tm, ytterbium Yb, mercury Hg;
   organic cations such as MDABCO=N-methyl-1,4-diazabicyclo[2.2.2]octane, ODABC=N-hydroxyl-N′-diazabicyclo[2.2.2]octonium;
   or an alloy of said elements of the second set of elements;
X selected from a third set of elements including halogens such as bromine Br, iodine I, chlorine Cl, fluorine F, or an alloy of said elements of the third set of elements.

Alternatively, the first material is a perovskite having the formula A₂C¹⁺D³⁺X₆, with:
A, X respectively selected from the first set of elements and the third set of elements;
C selected from a fourth group of elements including:
   inorganic cations such as gold Au, silver Ag, copper Cu, thallium Tl, lithium Li; cesium Cs, sodium Na, rubidium Rb, potassium K;
   or an alloy of said elements from the fourth set of elements;
D selected from a fifth group of elements including:
   inorganic cations such as gold Au, aluminum Al, gallium Ga, indium In, tin Sn, bismuth Bi, antimony Sb;
   or an alloy of said elements of the fourth set of elements.

Alternatively, the first material is a perovskite having the formula A₂B⁴⁺X₆ or A₃B₂³⁺X₉ with A, B, X respectively selected from the first set of elements, the second set of elements, and the third set of elements.

Alternatively, the first material is a chalcogenide or a rudorffite.

The first material is from the perovskite family and may have a 0-dimensional, 1-dimensional, 2-dimensional, or 3-dimensional structure.

At least one of the lateral dimensions (length, width) of the absorption layer AL is greater than 0.1 cm, preferably greater than 1 cm, and even more preferably greater than 10 cm. More specifically, the absorption layer AL has a surface area greater than 0.01 cm², preferably greater than 1 cm² and even more preferably greater than 100 cm². The thickness of the absorption layer AL is between a few hundred nm and several mm, for example 10 mm.

By way of example for the field of medical radiography and using a CsPbBr3-type perovskite composition, the following will be used:
a layer of CsPbBr₃ with a thickness between 100 μm and 400 μm for X-ray mammography,
a layer of CsPbBr₃ with a thickness greater than 0.65 mm for X-ray radiography (range 30 to 70 keV) to have >90% absorption,
a layer of CsPbBr₃ with a thickness greater than 1.4 mm for X-ray radiography (range 40 to 120 keV) to have >90% absorption.

The upper electrode EL2 is deposited onto the absorption layer AL. In the case illustrated, and without loss of generality, the upper electrode EL2 is made of a conductive layer common to all pixels Pxl. Alternatively, it is possible to make a plurality of upper electrodes EL2 made with several different electrically conductive layers deposited onto the absorption layer AL. The upper electrode EL2 may consist of a single layer or a stack of layers. It may also consist of at least one blocking layer to allow dark current to be minimized. This blocking layer may be semiconductive or insulating in nature. This blocking layer may, for example, be made of a dielectric polymer (polyester, polyimide, polycarbonate, PMMA, parylene, PVC) or semiconductive (poly-(3-hexylthiophene), also known as P3HT, poly(triarylamine), also known as PTAA, poly(9,9-dioctylfluorene-alt-N-(4-sec-butylphenyl)diphenylamine), also known as TFB).

In the illustrated example, the readout integrated circuit ROIC is made using a plurality of transistors and thin layers of conductive, semiconductor, or dielectric materials according to CMOS (Complementary Metal-Oxide-Semiconductor) technology or TFT technology in amorphous silicon or IGZO or organic (OTFT) silicon, on a second substrate sub2. For each pixel Pxl, a readout electrode EL_read is associated to read the signals generated by the photo charge carriers generated by the absorption layer AL of a pixel Pxl.

The device D1 also comprises a plurality of hybridization connectors CEM. By way of example, hybridization is performed for each pixel Pxl by means of a metal bead CEM electrically connected to the readout electrode EL_read associated exclusively with the same pixel. The bead CEM can, for example, be made with indium beads or copper micro-pillars, to allow each pixel to have individualized contact with the readout circuit. It is possible to use other means of hybridization to make the hybridization connectors CEM, for instance, but not limited to:
solder balls with at least one metal element (bump) made of Pb, Sn, Ag, Au, Cu, Bi or In, deposited by evaporation, screen printing, lithography, laser ablation, electrolytic deposition, or bead placement, then assembled by brazing, soldering, light-induced crosslinking, or thermocompression;
polymer balls (polymer bumps) deposited by screen printing and/or assembled by light-induced crosslinking or thermocompression;
Au, Cu, or Ni stud bumps assembled by thermocompression;
Cu pillars assembled by brazing,
a conductive adhesive layer (for example, carbon-based adhesive) sized so as to efficiently collect charges in the axis normal to the first substrate sub1 and to minimize electrical leakage in the plane parallel to the first substrate sub1;
an anisotropic conductive film (ACF) or anisotropic conductive adhesive ink.

More particularly, a film or ink based on magnetic beads that can be oriented under a magnetic field.

The first substrate sub1 is placed between the absorption layer AL and the plurality of hybridization connectors CEM. The first substrate sub1 comprises, for each pixel Pxl, at least one via V1 starting from the second face of the first substrate sub1 opposite the first face on which the absorption layer AL rests. The via V1 is a via extending through the substrate sub1. For each pixel Pxl, the at least one via V1 is an electrically conductive via having a lower end in contact with the hybridization connector CEM and another end in contact with the absorption layer AL. The at least one via V1 is filled with a second electrically conductive material.

Alternatively, the inner walls of the via V1 are covered with a second electrically conductive material. In the embodiment illustrated, the via V1 acts as the lower electrode EL1. For each pixel Pxl, the via V1 ensures electronic continuity between the absorption layer AL and the readout electrode EL_read dedicated to said pixel through the hybridization connector CEM. The aperture of a via V1 may be circular, parallelepiped-shaped, triangular, or any other shape. The surface area of the aperture of a via V1 of a pixel Pxl is preferably less than or equal to that of the readout electrode EL_read associated with said pixel Pxl. In the case of a cylindrical via, the diameter of a via V1 is between 100 nm and 10 mm. The second conductive material may be a metal (In, Bi, Sn, Pb, Cr, Pt, Ag, Au, Ti), a conductive organic material (polymer, graphene ink, carbon black-based ink, carbon nanotube-based ink), an ink based on Ag silver particles, a conductive oxide (ITO, SnO₂, TiO₂).

An electrical voltage is applied between the upper electrode EL2 and the lower electrode EL1, allowing the generated charges to be moved to the lower electrode EL1. The amount of generated charge carriers collected by the lower electrode EL1 determines the amplitude of the readout signal associated with the pixel Pxl.

The first substrate sub1 is made of an inorganic, organic or hybrid material. By way of example, the substrate sub1 is made of glass, plastic, silicon or ceramic. The first substrate sub1 may be a monolayer substrate or a stack of several layers of several materials. The thickness of the first substrate sub1 is between 1 μm and 10 mm.

Advantageously, the substrate sub1 has a regular, smooth and flat lower surface that facilitates indirect coupling with the electronic part. This offers the advantage of overcoming the problems of surface state, flatness and roughness of the surface of thick perovskite layers encountered in prior art hybridization solutions. Furthermore, it offers the possibility of reducing the lateral distance separating the lower electrodes and thus reducing the pixel pitch so as to increase the resolution of the detector.

Advantageously, the substrate sub1 is made of a material having a coefficient of thermal expansion in the range [CTE-50%, CTE+50%], where CTE is the coefficient of thermal expansion of the absorption layer AL. By way of example, for a CsPbBr₃ absorption layer, the thermal coefficient of the substrate sub1 is between 1.5×10^{-5°} K⁻¹ and 4.5×10^{-5°} K⁻¹. This allows resolution of the issues of differential thermal expansion encountered during high-temperature deposition of the absorption layer AL. The result is to improve the mechanical robustness of the absorption layer AL and to avoid curling or cracking phenomena following deposition and due to differential thermal expansion.

In general, the substrate sub1 has chemical, thermal, mechanical and electronic features that are suitable for the conditions of the process for depositing a perovskite layer. The substrate sub1 plays a dual role:
an electrical role: ensuring localized electrical continuity between these two faces so as to connect the absorption layer AL (source of generated charges) to the associated readout electrode EL_read.
a mechanical role: acting as a mechanical support for the absorption layer that is compatible with the particular constraints of perovskite deposition (high temperatures, chemical inertness, etc.) and the constraints associated with hybridization techniques.

Advantageously, the use of the first substrate sub1 with the vias V1 makes it possible to disocciate the manufacturing constraints of the perovskite absorption layer AL from the mechanical strength, thermal, chemical and electrical constraints of the readout circuit ROIC.

Advantageously, the upper surface of the first substrate sub1 comprises a germination layer made of a perovskite material so as to promote the growth by epitaxy or heteroepitaxy of the absorption layer AL. Alternatively, the first substrate sub1 has a crystal lattice that matches the lattice of the first material of which the absorption layer AL is composed.

For example, if the material of the absorption layer AL is CsPbBr₃, it may advantageously be possible to perform heteroepitaxy on a first substrate sub1, made of PbS, FeS₂ (pyrite), mica (for example muscovite), PbSnSe, or GaAs. If the material of the first substrate sub1 does not allow direct heteroepitaxy of the absorption layer AL, it is possible to go through an intermediate step by growing a surface layer by heteroepitaxy on the first substrate sub1 and then performing heteroepitaxy of the perovskite on this surface layer. For example, lead chalcogenides are compatible with perovskite heteroepitaxy, but they are difficult to obtain in wafer substrate form. Thus, it is possible to grow a layer of lead chalcogenides on the first substrate sub1 (for example by molecular beam epitaxy) and then grow the perovskite absorption layer on the lead chalcogenide layer.

Advantageously, the first substrate sub1 is made totally or partially of a material that is opaque to wavelengths in the visible, ultraviolet, or near-infrared range, or to X-rays or gamma rays. This allows the formation of localized or generalized optical shielding that protects the light-sensitive components of the readout circuit ROIC. By way of example, the performance of certain transistor technologies deteriorates when exposed to light or radiation. For example, transistors based on amorphous silicon or indium gallium zinc oxide (IGZO) are mentioned. Optical shielding may be achieved using an opaque layer in the structure of the first substrate sub1 or by integrating pigments into the volume of the first substrate sub1 (carbon black), or by introducing atoms of an element with a high atomic number (for example Bi carboxylate) onto the surface or in the volume of the substrate sub. In the case of local optical shielding, it is preferred to place the transistors of the readout circuit under the shielded zones of the first substrate sub1.

FIG. 2b illustrates a cross-sectional view of an example of hybridization of an optoelectronic device D1 according to a second embodiment of the invention. In the illustrated embodiment, the optoelectronic device D1 also comprises, for each via V1, an electrically conductive upper interface layer C1 deposited onto the first face of the first substrate sub1. The upper interface layer C1 is confined between the end of the associated via V1 and a volume of the absorption layer AL. Each upper interface layer C1 is thus deposited onto the upper face of the substrate sub1. Each via V1 opens onto the upper interface layer C1 associated therewith. The upper interface layer may be made of, but is not limited to, a metal (In, Bi, Sn, Pb, Cr, Pt), a conductive organic material (polymer, graphene ink, carbon black ink, carbon nanotube ink), Ag-based ink, a conductive oxide (ITO, SnO₂, TiO₂) or any other conductive material.

In the case where the via V1 is a conductive via, the lower electrode EL1 is formed of at least one via V1 and the upper interface layer C1 associated therewith. This variant has the advantage of increasing the charge collection area between the absorption layer AL and the via V1, thus improving the collection and transfer of the generated charges.

Alternatively, the upper interface layer C1 alone, or the assembly formed by the upper interface layer C1 and the second material filling each via V1, are formed of at least one material acting as a blocking layer (the material may be different between the upper interface layer C1 and the vias V1). Thus, the assembly acts as a blocking layer for one type of charge carrier (holes or electrons).

In the case where the blocking layer must block the injection of electrons, in the dark, from the lower electrode EL1 to the absorption layer AL, it must have an energy barrier of at least 0.4 eV. In the case where the blocking layer is a metal, this barrier is defined between the work function of the metal and the bottom of the conduction band of the semiconductor material of the absorption layer AL. In the case where the blocking layer is a semiconductor, this barrier is defined between the work function of the electrode metal and the bottom of the conduction band of said semiconductor (also called LUMO, for Lowest Unoccupied Molecular Orbital, in the case of organic semiconductors. This is also referred to as electron affinity).

In the case where the blocking layer must block the injection of holes, in the dark, from the lower electrode EL1 to the absorption layer AL, it must have an energy barrier of at least 0.4 eV. In the case where the blocking layer is a metal, this barrier is defined between the work function of the metal and the top of the valence band of the semiconductor material of the absorption layer AL. In the case where the blocking layer is a semiconductor, this barrier is defined between the work function of the conductive electrode and the top of the valence band of said semiconductor (also called HOMO, for Highest Occupied Molecular Orbital, in the case of organic semiconductors. This is also referred to as ionization potential). This variant has the advantage of minimizing the dark current of the detector device D1.

The materials that may be used as a blocking layer include, but are not limited to, organic, inorganic, or organic/inorganic hybrid dielectrics such as: SiO₂, HfO₂, Al₂O₃, LiF, MgF₂, polymers such as polyimide, PVC, PMMA, parylene, PC, PVDF, PVDF-TrFE, ceramics and perovskites. Alternatively, the materials used to act as blocking layers are organic, inorganic or organic/inorganic hybrid semiconductors such as silicon, SnO₂, TiO₂, NiOx, PTAA, TFB, P3HT, perylene diimide, acene diimide, fullerene and fullerene derivatives, and perovskites.

FIG. 2c illustrates a cross-sectional view of an example of hybridization of an optoelectronic device D1 according to a third embodiment of the invention. Compared to the first embodiment, the optoelectronic device D1 also comprises, for each via V1, a lower interface layer C2 that is electrically conductive and deposited onto the second face of the first substrate sub1. The lower interface layer C2 is in contact with the lower end of the associated via V1 and with the associated hybridization connector CEM. The lower interface layer C2 may be made of a metal (In, Bi, Sn, Pb, Cr, Pt), a conductive organic material (polymer, graphene ink, carbon black ink, carbon nanotube ink), Ag-based ink, a conductive oxide (ITO, SnO₂, TiO₂) or any other conductive material.

In the case where the via V1 is a conductive via, the lower electrode EL1 is formed by at least one via V1 and the lower interface layer C2 associated therewith. This variant has the advantage of improving the contact surface between the via V1 and the hybridization connector CEM. The improvement in the contact surface minimizes the electrical resistance for the transfer of charges from the absorption layer AL to the readout electrode El_read.

Alternatively, the second material filling each via V1, or the assembly formed by the second material filling each via V1 and the lower interface layer C2, comprises at least one material acting as a blocking layer (the material may be different between the lower interface layer C2 and the vias V1). Thus, the assembly acts as a blocking layer for one type of charge carrier (holes or electrons). The blocking layer in this variant can be made in a similar manner to the blocking layer described for the embodiment of FIG. 2b.

FIG. 2d illustrates a cross-sectional view of an example of hybridization of an optoelectronic device D1 according to a fourth embodiment of the invention. The device D1 comprises the upper interface layer C1 and the lower interface layer C2 as described previously.

If the via V1 is conductive, the lower electrode EL1 is formed by the combination of the via V1 with the associated upper interface layer C1 and lower interface layer C2.

Alternatively, the upper interface layer C1, or the assembly formed by the upper interface layer C1 and the second material filling each via V1, or the assembly formed by the upper interface layer C1 and the second material filling each via V1 and the lower interface layer C2, comprise at least one material acting as a blocking layer (the material may be different between the upper interface layer C1, the lower interface layer C2, and the vias V1). Thus, the assembly acts as a blocking layer for one type of charge carrier (holes or electrons). The blocking layer in this variant can be produced in a similar manner to the blocking layer described for the embodiment in FIG. 2b. This variant has the advantage of minimizing the dark current of the detector device D1. Alternatively, the second material filling each via V1 is a dielectric. The combination of the upper interface layer C1, the via V1, and the lower interface layer C2 forms a capacitive element Cap1 suitable for storing the generated electrical charges. This has the advantage of making a storage capacity integrated into the first substrate sub1 to accumulate the generated charges. It is thus possible to make optoelectronic devices with a function for accumulating the charges generated. The upper interface layer C1 simultaneously acts as the lower electrode EL1 of the photodetector structure and as the first conductive plate of the capacitive element Cap1. The lower interface layer C1 acts as the second conductive plate of the capacitive element Cap1. The via V1 filled with a dielectric acts as the insulating volume of the capacitive element Cap1. The dielectric material preferably has a dielectric permittivity greater than 10 and may be chosen from a composite with ceramic filler such as ZrO₂, TiO₂ or PZT, a polymer (PVDF), or a ceramic.

FIG. 2e illustrates a cross-sectional view of an example of hybridization of an optoelectronic device D1 according to a fifth embodiment of the invention. The capacitive element Cap1 is formed inside the via V1 through the following stack: electrical conductor M2/dielectric M1/electrical conductor M2′. The functionality of the via V1 as a capacitive element by means of an internal stack is compatible with all the embodiments of the invention described above.

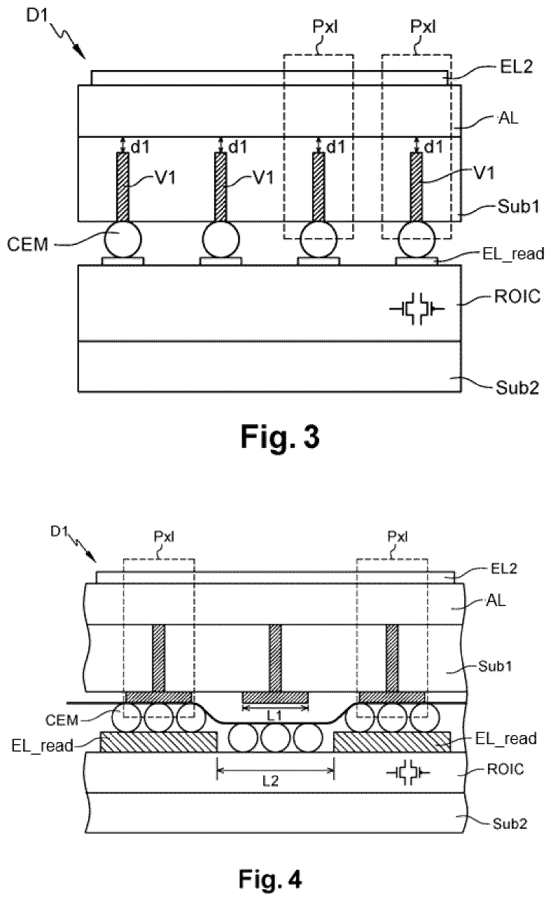

FIG. 3 illustrates a cross-sectional view of an example of hybridization of an optoelectronic device D1 according to a sixth embodiment of the invention. The first substrate sub1 is made of a dielectric or semiconductor material. The via V1 does not open onto the upper face of the first substrate sub1 from the lower face of the first substrate sub1. The via V1 is electrically conductive. The volume confined between the upper end of the via V1 and the upper face of the first substrate has a thickness d1 less than or equal to 100 μm, preferably less than 50 μm, and even more preferably less than 10 μm. When the device is not exposed to radiation, the confined volume acts as a blocking layer for the injection of charges from the lower electrode. This allows the dark current in the optoelectronic device D1 to be reduced. When the absorption layer AL is exposed to incident radiation, the dielectric zone d1 allows all or some of the electric field to propagate into the absorption layer AL, either by becoming slightly conductive under the incident radiation stream or by trapping charges at the interface between Sub1 and the absorption layer AL. The generated charges can then be read by capacitive effect.

FIG. 4 illustrates a cross-sectional view of an example of hybridization of an optoelectronic device D1 according to a seventh embodiment of the invention. The hybridization connector CEM is an anisotropic conductive layer. Preferably, the readout electrode EL_read has an outward topology relative to the surface of the second substrate sub2. The anisotropic conductive layer is, for example, an epoxy resin comprising conductive microbeads. Once formed into shape by compression, it is then electrically conductive only in the direction normal to the surface of the first substrate sub1. The diameter of at least one crushed bead is at least less than the inter-pixel distance L2. For each pixel Pxl, the electrode EL1 comprises a via V1 and preferably a lower interface layer C2. Each lower interface layer C2 has a width L1 that is less than the separation distance L2 between two adjacent readout electrodes EL_read. This allows indirect coupling to be performed without the need for an alignment step. Specifically, a lower interface layer C2 that is not aligned with a readout electrode EL_read does not pose a risk of short-circuiting between two adjacent readout electrodes EL_read due to the insertion of a misaligned lower interface layer C2.

Alternatively, each lower interface layer C2 has a width L1 that is less than the sum of the inter-pixel distance L2 and the width of the readout electrode EL_read.

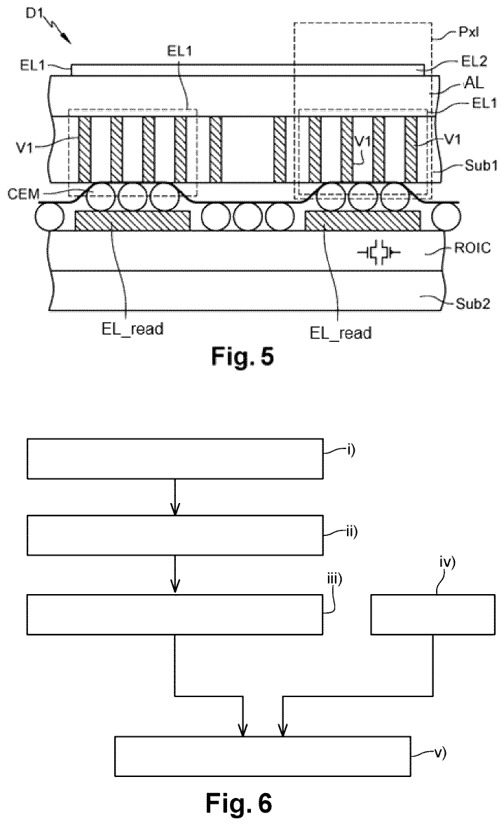

FIG. 5 illustrates a cross-sectional view of an example of hybridization of an optoelectronic device D1 according to an eighth embodiment of the invention. The hybridization connector CEM is an anisotropic conductive layer. Preferably, the readout electrode EL_read has an outward topology relative to the surface of the second substrate Sub2. The diameter of at least one crushed bead is at least less than the inter-pixel distance L2. For each pixel Pxl, the lower electrode EL1 is formed by a plurality of adjacent vias V1. Increasing the number of vias improves the conductivity of the lower electrode EL1 and thus promotes the collection of charges generated in the detection device D1. The surface area of the aperture of a via V1 of a pixel Pxl is less than or equal to that of the readout electrode EL_read associated with said pixel Pxl. The distance separating two vias V1 is less than the distance separating two adjacent readout electrodes EL_read.

FIG. 6 illustrates the steps of a process P1 for manufacturing an optoelectronic device D1 according to the invention.

The first step consists in manufacturing a first substrate sub1 comprising a plurality of vias V1. The first substrate sub1 has a first face and a second opposite face. The vias V1 may or may not be through-holes starting from the second face. According to a first variant, this step is performed by piercing the first substrate sub1. The piercing operation can be performed using a subtractive method, for example chemical or physical etching or laser ablation. A laser beam is applied to a single point on the second face of the substrate sub1 so as to pierce a hole by melting and evaporation. Nanometric-precision piercing can be performed by adjusting the wavelength and emission power according to the material of the first substrate sub1. The laser beam scans the selected zone to cut a hole in the volume of the first substrate sub1. For example, for a first substrate made of polyimide, a laser having a wavelength of 532 nm is suitable for making a series of vias V1 with a diameter of between 100 nm and 1000 μm. Laser technology offers a number of advantages relative to conventional methods: speed, precision, flexibility and economy. Furthermore, laser piercing reduces the sensitivity of the first substrate sub1 to burning, so as not to have an impact on the mechanical robustness of the substrate sub1.

Alternatively, it is possible to manufacture the first substrate sub1 comprising a plurality of vias V1 by filling a thermosetting resin into a fakir mat-type mold.

Once the pierced structure is obtained, the holes are totally or partially filled with one or more materials according to the embodiment of the invention manufactured. The filling may be complete or consist of a deposition on the inner walls. The materials inside a via V1 may be conductive, insulating, or a stack of several different materials.

The second step ii) consists in depositing an absorption layer AL on a first face of the first substrate sub1 as described previously. The absorption layer AL is made of a material of perovskite crystal structure. The absorption layer deposition may be performed by direct or indirect integration. Advantageously, the absorption layer is deposited by direct integration. In this case and in a non-exhaustive manner, the following techniques may be used: crystal growth by liquid, liquefaction, spraying, melt deposition, powder sintering, vacuum deposition by close-space sublimation (CSS), vacuum deposition by evaporation, spreading of microcrystal-based paste, epitaxy and heteroepitaxy.

The third step iii) consists in depositing an upper electrode EL2 onto the absorption layer AL. This step can be performed using standard techniques for deposition of thin metal layers or conductive inks.

The fourth step iv) consists in manufacturing a readout circuit ROIC on a second substrate sub2. The readout circuit ROIC has a plurality of different readout electrodes EL_read on its upper face. Each readout electrode EL_read is dedicated to a pixel Pxl. The manufacture of the plurality of different readout electrodes EL_read is performed, by way of example, by one or more sequences of conductive layer deposition, lithography, and etching used in the micro and nanotechnology industry. The fourth step iv) is independent of the preceding steps. The fourth step iv) may be performed prior to or simultaneously with steps i) to iii).

On conclusion of steps i) to iii), the manufacture of the photoconversion part D1_opt of the device D1 according to the invention is complete. On conclusion of the fourth step iv), the manufacture of the electronic part D1_elec of the device D1 according to the invention is complete.

The fifth step v) consists in assembling the photo-conversion part D1_opt with the electronic part D1_elec via hybridization connectors. The assembly is performed so as to electrically connect, for each pixel Pxl, at least one via V1 to the dedicated readout electrode El_read through at least one hybridization connector CEM. Optionally, a sub-step of alignment is performed during assembly so as to precisely align the photo-conversion part D1_opt relative to the electronic part D1_elec. It is possible to use different hybridization methods to make the hybridization connectors CEM, such as, but not limited to:
metal solder balls (bumps) assembled by brazing, soldering, or thermocompression;
polymer balls (polymer bumps) deposited by screen printing and assembled by light-induced crosslinking or by thermocompression;
a conductive adhesive layer sized so as to efficiently collect the charges in the axis normal to the first substrate sub1 and to minimize electrical leakage in the plane parallel to the first substrate sub1;
an anisotropic conductive film (ACF) or an anisotropic conductive adhesive ink.

To make the device D1 according to FIGS. 2b and 2d, the process P1 also comprises step ii′) of deposition of a plurality of upper interface layers C1 on the first face of the first substrate sub1 aligned with the upper ends of the vias V1. This step ii′) must be performed before step ii) of deposition of the absorption layer AL.

To make the device D1 according to FIGS. 2c and 2d, the process P1 also comprises a step ii″) of deposition of a plurality of lower interface layers C2 on the second face of the first substrate sub1 aligned with the lower ends of the vias V1. This step ii″) must be performed before the assembly step v).

Alternatively, step ii) of depositing the absorption layer AL on the first substrate sub1 is performed before the step of manufacturing the vias V1 in said first substrate sub1.

1. An optoelectronic device (D1) comprising:
at least one pixel (Pxl) comprising:
an absorption layer (AL) made of perovskite and arranged on a first face of a first substrate (sub1), the absorption layer being intended to convert incident radiation into electrical charges;
a lower electrode (EL1) for collecting the electrical charges;
and an upper electrode (EL2) arranged on the absorption layer (AL);
a readout circuit (ROIC) arranged on a second substrate (sub2) and comprising at least one readout electrode (EL_read) dedicated to the pixel (Pxl);
the first substrate (sub1) comprising at least one via (V1) starting from a second face of the first substrate (sub1) opposite said first face; said via (V1) being electrically connected on the one hand to the lower electrode (EL1) and on the other hand to at least one hybridization connector (CEM) for electrically and mechanically coupling the pixel (Pxl) to the readout electrode (EL_read) dedicated to said pixel (Pxl).

2. The optoelectronic device (D1) as claimed in claim 1, wherein the via (V1) opens from the second face of the first substrate (sub1) to the first face of the first substrate (sub1).

3. The optoelectronic device (D1) as claimed in claim 1, wherein the pixel (Pxl) also comprises, for each via (V1), an electrically conductive upper interface layer (C1) deposited onto the first face of the first substrate (sub1), the upper interface layer (C1) being confined between the end of the associated via (V1) and a volume of the absorption layer (AL).

4. The optoelectronic device (D1) as claimed in claim 3, wherein at least the via (V1) and/or the upper interface layer (C1) constitutes a blocking layer for a predetermined type of charge carrier.

5. The optoelectronic device (D1) as claimed in claim 2, wherein the pixel (Pxl) also comprises, for each via (V1), an electrically conductive lower interface layer (C2) deposited onto the second face of the first substrate (sub1); the lower interface layer (C2) being in contact with the lower end of the associated via (V1).

6. The optoelectronic device (D1) as claimed in claim 5, wherein the width (L1) of the lower interface layer (C2) is less than the separation distance (L2) between two adjacent readout electrodes (EL_read).

7. The optoelectronic device (D1) as claimed in claim 1, wherein:
the via (V1) is filled with a second electrically conductive material;
or the inner walls of the via (V1) are covered with a second electrically conductive material.

8. The optoelectronic device (D1) as claimed in claim 5,
wherein at least the via (V1) and/or the upper interface layer (C1) constitutes a blocking layer for a predetermined type of charge carrier; and
wherein the via (V1) is filled with a dielectric material;
the assembly formed by the upper interface layer (C1), the via (V1) and the lower interface layer (C2) forming a capacitive element (Cap1) suitable for storing the electrical charges generated.

9. The optoelectronic device (D1) as claimed in claim 1, wherein the via (V1) is filled with a stack comprising a dielectric material (M1) confined between two electrically conductive materials (M2, M2′) so as to form a capacitive element (Cap1) in the via suitable for storing the electrical charges generated.

10. The optoelectronic device (D1) as claimed in claim 1, wherein the via (V1) does not open onto the first face of the first substrate (sub1) from the second face of the first substrate (sub1); the first substrate being made of a dielectric or semiconductor material; the via (V1) being conductive.

11. The optoelectronic device (D1) as claimed in claim 1, wherein the first substrate (sub1) has a crystal structure that matches that of the first material.

12. The optoelectronic device (D1) as claimed in claim 1, wherein the first substrate (sub1) is opaque to wavelengths in the visible range and/or to X-rays or gamma rays.

13. The optoelectronic device (D1) as claimed in claim 1, wherein the first material is CsPbBr₃ perovskite.

14. A matrix image sensor comprising an optoelectronic device as claimed in claim 1.
